(19) United States
(12) Patent Application Publication
(10) Pub. No.: US 2025/0229810 A1
(43) Pub. Date: Jul. 17, 2025

(54) OVERHEAD CARRIER VEHICLE

(71) Applicant: Murata Machinery, Ltd., Kyoto-shi, Kyoto (JP)

(72) Inventor: Makoto KOBAYASHI, Ise-shi (JP)

(21) Appl. No.: 18/853,817

(22) PCT Filed: Apr. 6, 2023
(86) PCT No.: PCT/JP2023/014256

§ 371 Date: Oct. 3, 2024

(30) Foreign Application Priority Data
May 9, 2022 (JP) 2022-076957

(51) Int. Cl. B61F 13/00; B61B 3/02; H01L 21/677

(52) U.S. Cl. CPC B61F 13/00; B61B 3/02; H01L 21/67733

(57) ABSTRACT

An overhead transport vehicle includes: a traveling portion including traveling wheels to travel on a traveling rail, and a main body supported by the traveling portion via a suspension and configured to hold an object to be transported. The overhead transport vehicle includes a contact roller to contact with a curved outside portion of the traveling rail in a curved section from below on an upper surface of the main body facing the traveling rail in a vertical direction.

### BACKGROUND OF THE INVENTION

### 1. Field of the Invention

The present invention relates to overhead transport vehicles.

### 2. Description of the Related Art

An overhead transport vehicle is known to travel along a traveling rail installed on the ceiling or the like of a building such as a factory. For example, WO 2012/157319 discloses an overhead transport vehicle including a traveling portion traveling on a traveling rail and a main body holding an article. In the overhead transport vehicle of WO 2012/157319, the traveling portion travels inside a tube of the traveling rail formed in a rectangular tubular shape, and the main body is supported by the traveling portion in a suspended manner via a slit provided in a lower surface portion of the traveling rail.

### SUMMARY OF THE INVENTION

In the overhead transport vehicle with such a configuration, traveling wheels of the traveling portion may float through the centrifugal force when traveling through a curved section and may fail to stably travel through the curved section.

Example embodiments of the present invention provide overhead transport vehicles that each reduce a floating amount of traveling wheels when a traveling portion travels through a curved section.

An overhead transport vehicle according to an example embodiment of the present invention includes a traveling portion including traveling wheels to roll on a traveling rail, and a main body supported by the traveling portion via a suspension and configured to hold an object to be transported, the overhead transport vehicle being provided with a contact roller to contact with a curved outside portion of the traveling rail in a curved section from below on an upper surface of the main body facing the traveling rail in a vertical direction.

In the overhead transport vehicle including the main body with a configuration suspended from the traveling portion, the main body is inclined by the centrifugal force when traveling through the curved section, bringing the curved outside portion of the main body closer to the traveling rail. However, in an overhead transport vehicle according to an example embodiment of the present invention, the contact roller coming into contact with the curved outside portion of the traveling rail in the curved section from below is provided on the upper surface of the main body. This enables, when the curved outside portion of the main body is about to approach the traveling rail, the contact roller to come into contact with the curved outside portion of the traveling rail, and the reaction force at that time restricts the approaching of the curved outside portion of the main body to the traveling rail. Consequently, the inclination of the main body, and thus the inclination of the traveling portion suspending and supporting the main body are prevented, and a floating amount of the traveling wheels when the traveling portion travels through the curved section can be reduced. The curved outside portion of the traveling rail referred to here is a portion of the traveling rail outside a center line in the width direction.

In an overhead transport vehicle according to an example embodiment of the present invention, the traveling rail may include a slit portion through which the suspension is movable during traveling of the traveling portion, and a pair of rolling portions on which the traveling wheels roll, the pair of rolling portions facing each other across the slit portion in a width direction perpendicular or substantially perpendicular to both the vertical direction and a traveling direction of the traveling portion, and the contact roller may contact with one of the pair of rolling portions on a curved outside in the curved section. With this configuration, the contact roller comes into contact with one rolling portion disposed on the curved outside out of the pair of rolling portions in the curved section. This enables the reaction force when the contact roller comes into contact with the one lower surface portion to restrict the approaching of the curved outside portion of the main body to the traveling rail (the rolling portion).

An overhead transport vehicle according to an example embodiment of the present invention may further include an elevator to lift and lower the contact roller in the vertical direction. With this configuration, when the contact roller is desired to be brought into contact with the traveling rail, the contact roller can be surely brought into contact with the traveling rail, and when the contact roller is desired to be separated from the traveling rail, the contact roller can be surely separated from the traveling rail.

In an overhead transport vehicle according to an example embodiment of the present invention, a trapezoidal screw may be included in a linear motion mechanism of the elevator. With this configuration, a simple configuration can counter the reaction force when the contact roller comes into contact with the traveling rail without requiring a complicated mechanism such as a brake mechanism, for example.

An overhead transport vehicle according an example embodiment of the present invention may further include a controller configured or programmed to control the lifting mechanism such that the contact roller comes into contact with the traveling rail at least when the traveling portion travels through the curved section. With this configuration, the contact roller can be brought into contact with the curved outside portion of the traveling rail more surely in the curved section.

In an overhead transport vehicle according to an example embodiment of the present invention, the contact roller may be rotatably provided, and an orientation of the contact roller may be provided so as to enable rocking with respect to a direction perpendicular or substantially perpendicular to a rotational axis direction when viewed from the vertical direction. With this configuration, the orientation of the contact roller can be changed so as to be along the traveling direction of the traveling portion, and thus the contact roller rotates well during traveling of the overhead transport vehicle. This can prevent the contact roller from sliding on the traveling rail and prevent the contact roller from wearing due to the traveling direction of the traveling portion and the orientation of the contact roller not matching.

In an overhead transport vehicle according to an example embodiment of the present invention, the contact roller may be provided at a central portion of the main body in the traveling direction of the traveling portion. With this configuration, even if the orientation of the contact roller is not able to oscillate, there is a high possibility that the traveling direction of the traveling portion and the orientation of the contact roller will match in the curved section. This can prevent the contact roller from sliding on the traveling rail and prevent the contact roller from wearing due to the traveling direction of the traveling portion and the orientation of the contact roller not matching.

Example embodiments of the present invention can reduce the floating amount of the traveling wheels when the traveling portion travels through the curved section.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic configuration diagram of an overhead transport vehicle system according to an example embodiment of the present invention.

FIG. 2 is a front view of the overhead transport vehicle in FIG. 1 when viewed from the front.

FIG. 3 is a side view of the overhead transport vehicle in FIG. 1 when viewed from a side.

FIG. 4 is a sectional view illustrating a traveling rail portion in FIG. 2 in an enlarged manner.

FIGS. 5A to 5C are diagrams illustrating the operation of an inclination prevention mechanism.

FIG. 6A is a schematic configuration diagram of the inclination prevention mechanism when viewed from above. FIG. 6B is a schematic configuration diagram of a contact roller when viewed from above. FIG. 6C is a diagram illustrating a positional relation between an optical sensor and a blocking plate when viewed from the front.

FIG. 7A is a perspective view of the contact roller. FIG. 7B is a perspective view of the contact roller when viewed from a direction different from that in FIG. 7A. FIG. 7C is a side view of the contact roller.

FIGS. 8A to 8C are diagrams illustrating the operation of the inclination prevention mechanism included in an overhead transport vehicle according to a modification of an example embodiment of the present invention.

### DETAILED DESCRIPTION OF THE EXAMPLE EMBODIMENTS

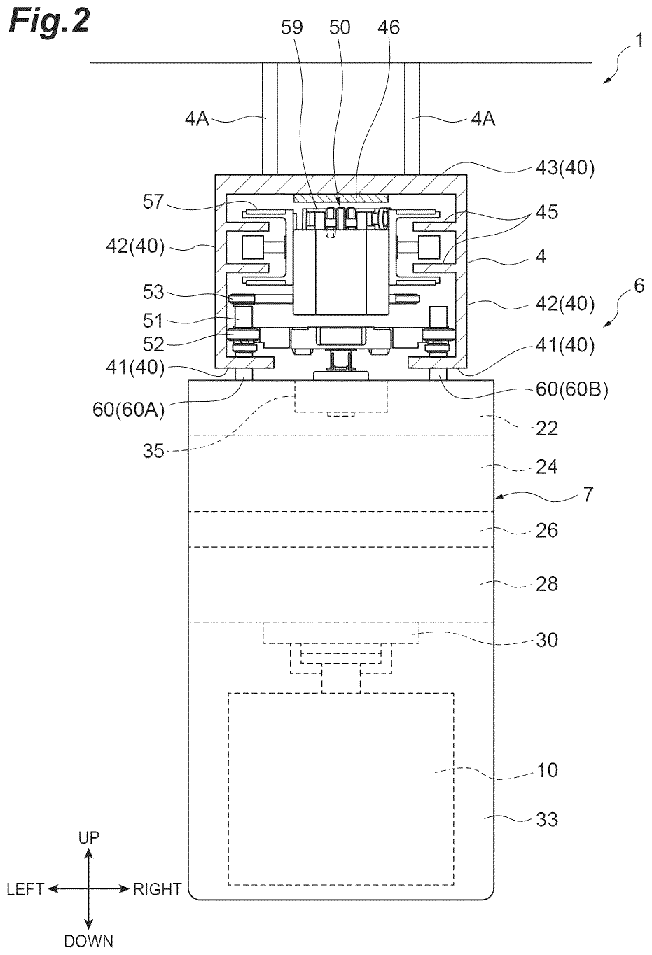

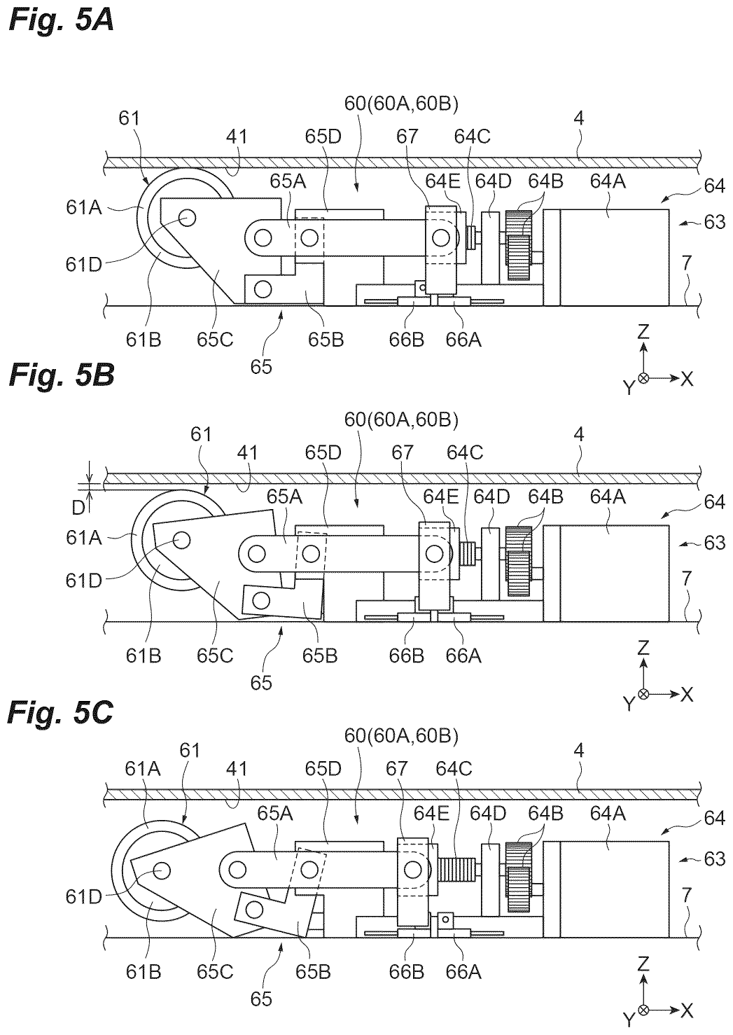

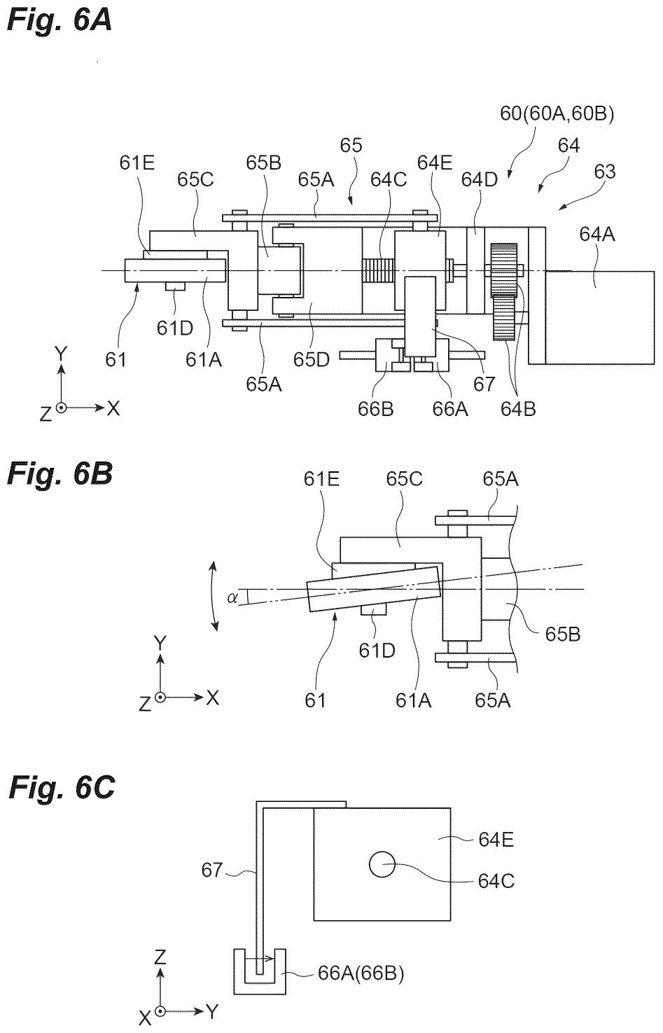

Example embodiments will now be described in detail with reference to the drawings. In the description of the drawings, like elements are designated by like reference signs, and duplicate description is omitted. In FIG. 2 to FIG. 4, for the convenience of description, “up,” “down,” “left,” “right,” “front,” and “rear” directions are defined. In FIGS. 5A to 5C and FIGS. 6A to 6C, for the convenience of description, an X axis, a Y axis, and a Z axis orthogonal to each other are defined.

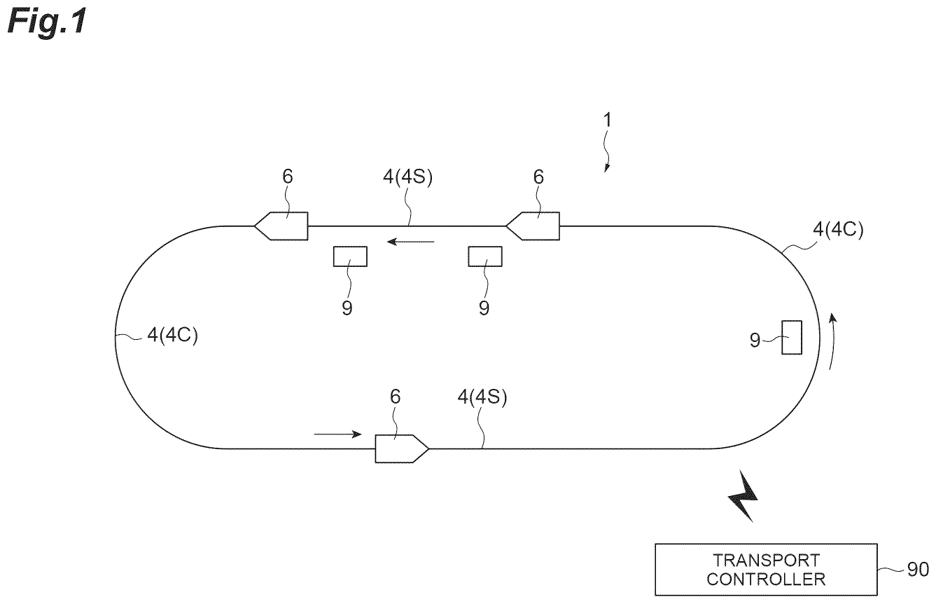

An overhead transport vehicle 6 according to the present example embodiment (hereinafter referred to as a “transport vehicle 6”) is used for an overhead transport vehicle system 1 illustrated in FIG. 1. The overhead transport vehicle system 1 is a system configured to transport an article (an object to be transported) 10 between loading portions 9 using the transport vehicle 6 capable of moving along a traveling rail 4. Examples of the article 10 include containers such as a front opening unified pod (FOUP) that store a plurality of semiconductor wafers and reticle pods that store glass substrates, and general components, and the like. The overhead transport vehicle system 1 includes the traveling rail 4, a plurality of the transport vehicles 6, and a plurality of the loading portions 9.

As illustrated in FIG. 1, the loading portion 9 is disposed along the traveling rail 4 and is provided at a position where the transport vehicle 6 can deliver the article 10. The loading portion 9 includes a buffer and a delivery port. The buffer is a loading portion where the article 10 is temporarily placed. The buffer is a loading portion where the article 10 is temporarily placed when, for example, the article 10 that is being transported by the transport vehicle 6 cannot be transferred to a delivery port as a destination for some reasons such as that the delivery port has another article 10 placed thereon. The delivery port is a loading portion to perform delivery of the article 10 to and from a semiconductor processing device (not illustrated) including a cleaning apparatus, a deposition apparatus, a lithography apparatus, an etching apparatus, a thermal treatment apparatus, and a planarization apparatus. The processing device is not limited to a particular device and may be various devices.

For example, the loading portion 9 is disposed by the traveling rail 4. In this case, the transport vehicle 6 transversely feeds a lifting drive unit 28 or the like by a transversely feeding unit 24 and lifts and lowers a lifting platform 30 (refer to FIG. 2) to perform delivery of the article 10 from or to the loading portion 9. Although not illustrated, the loading portion 9 may be disposed immediately below the traveling rail 4. In this case, the transport vehicle 6 lifts and lowers the lifting platform 30 to deliver the article 10 from or to the loading portion 9.

The traveling rail 4 is laid, for example, near the ceiling that is a space overhead of an operator. The traveling rail 4 is suspended from, for example, the ceiling. The traveling rail 4 is a predetermined traveling path allowing the transport vehicles 6 to travel thereon. The transport vehicles 6 move on the traveling rail 4 in one predetermined direction. The traveling rail 4 is supported by pillars 4A, 4A (refer to FIG. 2).

As illustrated in FIG. 2 to FIG. 4, the traveling rail 4 includes a rectangular tubular rail main body 40 including a pair of lower surface portions (rolling portions) 41, 41, a pair of side surface portions 42, 42, and an upper surface portion 43, power supply portions 45, and a magnetic plate 46. The rail main body 40 defines an inside space S through which a traveling portion 50 of the transport vehicle 6 travels. The lower surface portions 41 extend in a traveling direction of the transport vehicle 6 to form a lower surface of the rail main body 40. The lower surface portions 41 are plate-shaped structures causing traveling rollers (traveling wheels) 51 of the transport vehicle 6 to roll and causing the traveling portion 50 to travel. The side surface portions 42 are erected from (crosses) the lower surface portions 41. The side surface portions 42 extend in the traveling direction of the transport vehicle 6 to define side surfaces of the rail main body 40. The upper surface portion 43 extends in the traveling direction of the transport vehicle 6 to define an upper surface of the rail main body 40.

Between the pair of lower surface portions 41, 41 facing in a width direction (a right and left direction) orthogonal to an extension direction of the traveling rail 4, a slit portion G is formed through which a suspension 8 of the traveling portion 50, which is described in detail below, passes during traveling. The slit portion G extends along the extension direction of the traveling rail 4. In other words, the pair of lower surface portions 41, 41 face each other across the slit portion G in the width direction.

The power supply portions 45 supply power to power supply cores 57 of the transport vehicle 6 and perform transmission and reception of signals to and from the power supply cores 57. The power supply portions 45 are fixed to the pair of respective side surface portions 42, 42 and extend along the traveling direction. The power supply portions 45 supply power in non-contact with the power supply cores 57. The magnetic plate 46 generates magnetic force to travel or stop in a linear DC motor (LDM) 59 of the transport vehicle 6. The magnetic plate 46 is fixed to the upper surface portion 43 and extends along the traveling direction.

The transport vehicle 6 travels along the traveling rail 4 to transport the article 10. The transport vehicle 6 is configured such that the article 10 is able to be transferred. The transport vehicle 6 is an overhead traveling type unmanned transport vehicle. The number of the transport vehicles 6 included in the overhead transport vehicle system 1 is not limited to a particular number, and is two or more. The transport vehicle 6 includes a main body 7, the traveling portion 50, and a main body controller (a controller) 35. The main body 7 includes a main body frame 22, the transversely feeding unit 24, a 0 drive 26, the lifting drive unit 28, the lifting platform 30, and a cover 33.

The main body frame 22 is connected to the traveling portion 50 via the suspension 8 and supports the transversely feeding unit 24, the θ drive 26, the lifting drive unit 28, the lifting platform 30, and the cover 33. The transversely feeding unit 24 transversely feeds the θ drive 26, the lifting drive unit 28, and the lifting platform 30 all together in the width direction (the right and left direction) orthogonal to the traveling direction of the traveling rail 4. The θ drive 26 rotates at least either the lifting drive unit 28 or the lifting platform 30 within a predetermined angle range in a horizontal plane. The lifting drive unit 28 winds or pays out suspending members such as wires, ropes, and belts, thereby lifting or lowering the lifting platform 30. The lifting platform 30 is provided with a chuck, which can freely grasp or release the article 10. A pair of covers 33 are, for example, provided at the front and the rear of the transport vehicle 6 in the traveling direction. The cover 33 extends and retracts a claw or the like, which is not illustrated, to prevent the article 10 from falling during transport.

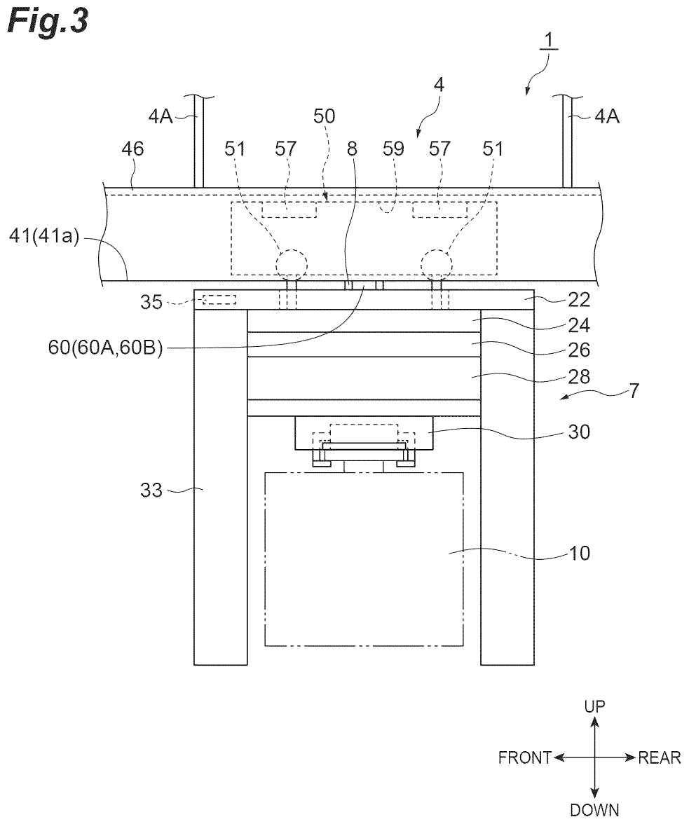

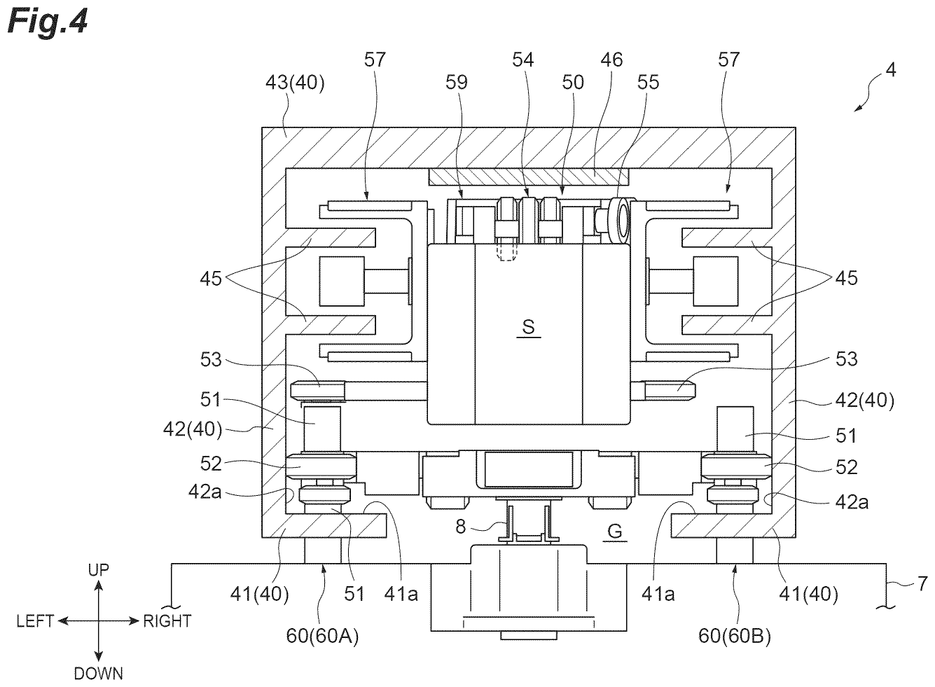

As illustrated in FIG. 3 and FIG. 4, the traveling portion 50 causes the transport vehicle 6 to travel along the traveling rail 4. The traveling portion 50 includes the traveling rollers 51, side rollers 52, branching rollers 53, an auxiliary roller 54, an inclined roller 55, the power supply cores 57, the LDM 59, and an inclination prevention mechanism 60.

The traveling rollers 51 are disposed at both right and left ends at the front and the rear of the traveling portion 50. The traveling rollers 51 roll on inner faces 41a, 41a of the pair of lower surface portions 41, 41 of the rail main body 40. The side rollers 52 are provided so as to be able to come into contact with inner faces 42a of the side surface portions 42 of the rail main body 40.

The branching rollers 53 are provided in order to switch branching of the transport vehicle 6 (the traveling portion 50) right and left at branching points of the traveling rail 4. More specifically, the branching rollers 53 switch the direction of the transport vehicle 6 to travel by being guided by guide members provided at the branching points.

The branching rollers 53 are provided so as to be able to come into contact with guides (not illustrated) disposed at connections, branches, and the like of the traveling rail 4. The auxiliary roller 54 includes a group of rollers in a set of three provided at the front and the rear of the traveling portion 50. The auxiliary roller 54 is provided in order to prevent the LDM 59, the power supply cores 57, and the like from coming into contact with the magnetic plate 46 disposed on the upper surface portion 43 of the traveling rail 4 when the traveling portion 50 is inclined to the front and the rear due to acceleration and deceleration or the like. The inclined roller 55 is inclined from a front and rear direction. The inclined roller 55 is provided in order to prevent inclination due to the centrifugal force when the traveling portion 50 travels through a curved section.

The power supply cores 57 sandwich the LDM 59 in the right and left direction at the front and the rear of the traveling portion 50. The power supply cores 57 perform non-contact power supply and non-contact transmission and reception of various signals with the power supply portions 45 disposed in the traveling rail 4. The power supply cores 57 exchange signals with the main body controller 35. The LDM 59 is provided at the front and the rear of the traveling portion 50. The LDM 59 generates a magnetic force to travel or stop with the magnetic plate 46 disposed on the upper surface portion 43 of the traveling rail 4 by an electromagnet.

As illustrated in FIG. 1, the traveling rail 4 includes a straight section 4S and a curved section 4C. The inclination prevention mechanism 60 illustrated in FIG. 2 to FIG. 4 is a mechanism configured to prevent the traveling portion 50 and the main body 7 from being inclined due to the centrifugal force when the transport vehicle 6 travels through the curved section 4C. The inclination prevention mechanism 60 is provided on the upper surface of the main body 7. The inclination prevention mechanism 60 is a mechanism configured to bring a contact roller 61 included in the inclination prevention mechanism 60 into contact with an outer surface of the lower surface portion 41 of the traveling rail 4 from below when traveling through the curved section 4C to prevent the main body 7 from being inclined by the reaction force obtained from the traveling rail 4.

As illustrated in FIG. 4, the inclination prevention mechanism 60 is disposed near the right and left ends in the width direction on the upper surface of the main body 7. That is, the inclination prevention mechanism 60 includes a left inclination prevention mechanism 60A and a right inclination prevention mechanism 60B. The contact roller 61 included in the left inclination prevention mechanism 60A is provided so as to come into contact with the left lower surface portion 41 out of the pair of lower surface portions 41, 41 defining the traveling rail 4. The contact roller 61 included in the right inclination prevention mechanism 60B is provided so as to come into contact with the right lower surface portion 41 out of the pair of lower surface portions 41, 41 forming the traveling rail 4. As illustrated in FIG. 3, the contact roller 61 included in the inclination prevention mechanism 60 is provided at a central portion of the main body 7 in the front and rear direction.

The contact roller 61 of the inclination prevention mechanism 60 comes into contact with one lower surface portion 41 disposed on the curved outside in the curved section 4C out of the pair of lower surface portions 41, 41 of the traveling rail 4. Specifically, when the left lower surface portion 41 in FIG. 4 is positioned on the curved outside in the curved section 4C, the contact roller 61 included in the left inclination prevention mechanism 60A comes into contact with the left lower surface portion 41, and when the right lower surface portion 41 in FIG. 4 is positioned on the curved outside in the curved section 4C, the contact roller 61 included in the right inclination prevention mechanism 60B comes into contact with the right lower surface portion 41.

As illustrated in FIGS. 5A and 6A, the inclination prevention mechanism 60 includes a lifting mechanism (elevator) 63 configured to move (lift and lower) the contact roller 61 in the Z-axis direction (in the vertical direction). This enables the inclination prevention mechanism 60 to perform control to bring the contact roller 61 into contact with the outer surface of the lower surface portion 41 of the traveling rail 4 or control to separate the contact roller 61 away from the outer surface of the lower surface portion 41.

The lifting mechanism 63 includes a linear motion mechanism 64 and an oscillating mechanism 65. The linear motion mechanism 64 includes a drive unit 64A, a gear 64B, a trapezoidal screw 64C, a support 64D, and a moving block 64E. The drive unit 64A is, for example, a motor. Rotational drive in the drive unit 64A is transmitted to the trapezoidal screw 64C via a plurality of the gears 64B. The trapezoidal screw 64C is screwed to the moving block 64E. The moving block 64E with such a configuration moves linearly in the X-axis direction by the trapezoidal screw 64C rotating. The moving block 64E is, for example, configured to move in the left direction illustrated in FIG. 5A by the trapezoidal screw 64C rotating in a positive direction (clockwise) and to move in the right direction illustrated in FIG. 5A by the trapezoidal screw 64C rotating in a negative direction (counterclockwise).

The oscillating mechanism 65 includes a first link member 65A, a second link member 65B, a third link member 65C, and a support 65D. The first link member 65A is movably supported by the support 65D along the X-axis direction. The first link member 65A is rotatably supported at one end on the moving block 64E and is rotatably supported at the other end on the third link member 65C. The first link member 65A is movable along the X-axis direction integrally with the moving block 64E.

The second link member 65B is rotatably fixed at one end to the support 65D and is rotatably fixed at the other end to the third link member 65C. Between the second link member 65B and the support 65D, an elastic member is provided configured to bias the second link member 65B so that the second link member 65B rotates clockwise about a rotation axis of the support 65D. The third link member 65C is rotatably fixed to both the other end of the first link member 65A and the other end of the second link member 65B. The contact roller 61 is fixed to the third link member 65C. With this configuration of the linear motion mechanism 64 and the oscillating mechanism 65, if the moving block 64E of the linear motion mechanism 64 moves in the left direction along the X-axis direction, the height position (the position the Z-axis direction) of the contact roller 61 fixed to the third link member 65C of the oscillating mechanism 65 is lowered (refer to FIG. 5C). On the other hand, if the moving block 64E of the linear motion mechanism 64 moves in the right direction along the X-axis direction, the height position (the position in the Z-axis direction) of the contact roller 61 fixed to the third link member 65C of the oscillating mechanism 65 is lifted (refer to FIG. 5A).

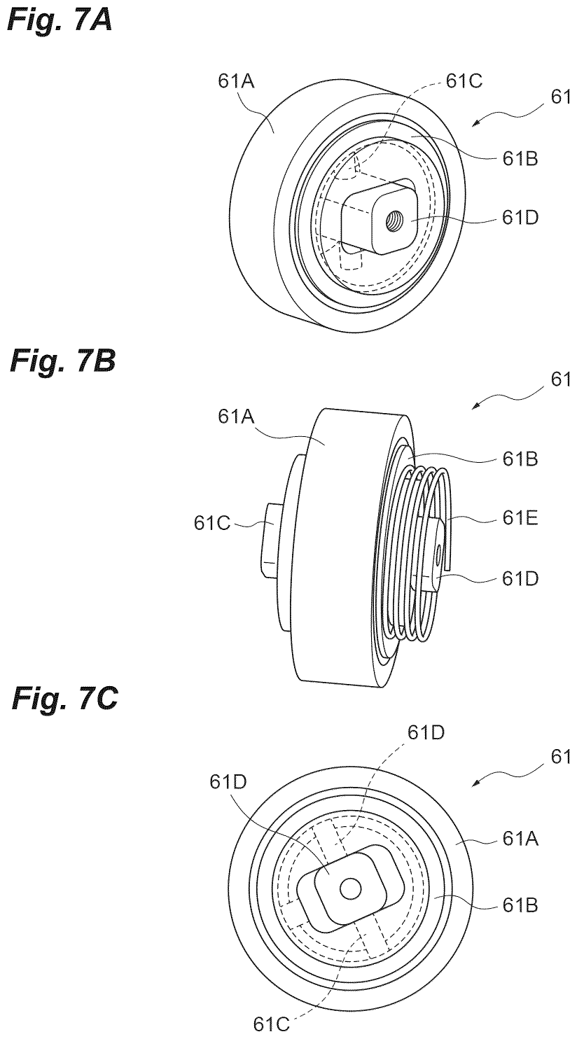

As illustrated in FIG. 6A, the contact roller 61 is mounted on the third link member 65C. As illustrated in FIGS. 7A to 7C, the contact roller 61 includes a rotating portion 61A, a rotation support (a rotating shaft) 61B, a first shaft portion 61C, a second shaft portion 61D, and a spring member 61E. The rotating portion 61A is a portion rolling on the lower surface portion 41 of the traveling rail 4 and is provided rotatably with respect to the rotation support 61B. The rotation support 61B is a ring-shaped member rotatably supporting the rotating portion 61A. The first shaft portion 61C is a portion passing through the center of the rotation support 61B in a radial direction and extends in the radial direction and is formed integrally with the rotation support 61B. The first shaft portion 61C has a predetermined caster angle. The second shaft portion 61D is a member mounted on the third link member 65C and is a member extending in one direction. The first shaft portion 61C is provided rotatably about the second shaft portion 61D. The rotation support 61B is mounted on the third link member 65C via the spring member 61E.

With such a configuration of the contact roller 61, as illustrated in FIG. 6B, the orientation of the contact roller 61 (the two dotted line) is provided so as to enable rocking with respect to the direction (the one dotted line) orthogonal to the first shaft portion 61C when viewed from the vertical direction (the Z-axis direction). The orientation of the contact roller 61 referred to here is the straight line connecting the front end and the rear end in a plan view of the contact roller 61. The contact roller 61, for example, oscillates by the acting force received from the traveling rail 4 during traveling on the traveling rail 4.

As illustrated in FIG. 1 and FIG. 2, the traveling portion 50 is controlled by a transport controller 90, which is described in detail below, via the main body controller 35. Specifically, commands from the transport controller 90 are transmitted to the main body controller 35, and the main body controller 35 having received the commands controls the traveling portion 50.

The main body controller (the controller) 35 is an electronic control unit including a central processing unit (CPU), a read only memory (ROM), a random access memory (RAM), and the like. The main body controller 35 is configured or programmed to control various of the transport vehicle 6. operations Specifically, the main body controller 35 is configured or programmed to control the traveling portion 50, the transversely feeding unit 24, the θ drive 26, the lifting drive unit 28, the lifting platform 30, and the inclination prevention mechanism 60. The main body controller 35 can be configured as software, for example, in which a program stored in the ROM is loaded onto the RAM and executed by the CPU. The main body controller 35 may be configured as hardware including electronic circuitry or the like. The main body controller 35 is configured or programmed to communicate with the transport controller 90 (refer to FIG. 1) using the power supply portions 45 (feeder lines) or the like of the traveling rail 4.

The main body controller 35 according to the present example embodiment is configured or programmed to control the lifting mechanism 63 of the inclination prevention mechanism 60 and can switch the position of the contact roller 61 to any of a first state S1, in which the contact roller 61 is positioned in contact with the lower surface portion 41 of the traveling rail 4 (the position in which the contact roller 61 is lifted to the maximum in the lifting mechanism 63) as illustrated in FIG. 5A, a second state S2, in which the contact roller 61 is separate from the lower surface portion 41 of the traveling rail 4 by a distance D as illustrated in FIG. 5B, and a third state S3, in which the contact roller 61 is lowered to the maximum in the lifting mechanism 63 as illustrated in FIG. 5C. Note that the distance D is set based on an allowed floating amount of the traveling rollers 51.

The main body controller 35 is configured or programmed to control the lifting mechanism 63 so as to be in the first state S1 when the transport vehicle 6 transfers the article 10 to the loading portion 9. More specifically, the main body controller 35 is configured or programmed to control the lifting mechanism 63 so as to be in the first state S1 when the transport vehicle 6 transfers the article 10 to the loading portion 9 disposed below and at the right or below and at the left of the traveling rail 4 instead of the loading portion 9 disposed immediately below the traveling rail 4. Specifically, when viewed from the front in the traveling direction of the transport vehicle 6, the main body controller 35 brings the contact roller 61 included in the right inclination prevention mechanism 60B illustrated in FIG. 4 into contact with the right lower surface portion 41 when the article 10 is transferred to the loading portion 9 disposed below and at the left of the traveling rail 4 and brings the contact roller 61 included in the left inclination prevention mechanism 60A illustrated in FIG. 4 into contact with the left lower surface portion 41 when the article 10 is transferred to the loading portion 9 disposed below and at the right of the traveling rail 4.

The main body controller 35 is configured or programmed to control the lifting mechanism 63 so as to be in the second state S2 when the transport vehicle 6 travels at least through the curved section 4C. Specifically, when the transport vehicle 6 travels through the curved section, the main body controller 35 brings the contact roller 61 included in the left inclination prevention mechanism 60A into contact with the left lower surface portion 41 in a case where the left lower surface portion 41 in FIG. 4 is positioned on the curved outside, and brings the contact roller 61 included in the right inclination prevention mechanism 60B into contact with the right lower surface portion 41 in a case where the right lower surface portion 41 in FIG. 4 is positioned on the curved outside.

The main body controller 35 controls the lifting mechanism 63 so as to be the third state S3 except during the transfer or during traveling through the curved section 4C, for example.

The lifting mechanism 63 includes two optical sensors 66A, 66B. Each of the optical sensors 66A, 66B includes, for example, a light emitter and a light receiver and detects the presence or absence of the reception of light from the light emitter in the light receiver. As illustrated in FIG. 6C, the moving block 64E has a blocking plate 67 mounted thereon that is capable of passing through between the light emitters and the light receivers of the two optical sensors 66A, 66B disposed side by side in the X-axis direction. The two optical sensors 66A, 66B are disposed such that the optical sensor 66A is in non-detection by the blocking plate 67 in the first state S1, both the optical sensors 66A, 66B are in non-detection by the blocking plate 67 in the second state S2, and the optical sensor 66B is in non-detection by the blocking plate 67 in the third state S3. The main body controller 35 switches the state of the contact roller 61 based on detection results of the two optical sensors 66A, 66B.

In a plan view of the pair of side surface portions 42, 42 of the traveling rail 4, the curved outside in the traveling rail 4 includes the side surface portion 42 side as a larger curve radius (a smaller curvature) side, and the curve inside in the traveling rail 4 includes the side surface portion 42 side as a smaller curve radius (a larger curvature) side. The curved outside portion in the traveling rail 4 includes a portion on the side surface portion 42 side with a larger curve radius than a center line in the width direction, and the curve inside portion in the traveling rail 4 includes a portion on the side surface portion 42 side with a smaller curve radius than the center line in the width direction. In the lower surface portions 41, the side surface portions 42, and the upper surface portion 43, the surface in contact with the inside space S is called an inner surface, and the surface opposite the inner surface, that is, the surface in contact with outside space is called an outer surface.

The following describes a working effect of the overhead transport vehicle system 1 according to the above example embodiment. As illustrated in FIG. 2, in the transport vehicle 6 with a configuration in which the main body 7 is suspended from the traveling portion 50, the main body 7 is inclined by the centrifugal force when traveling through the curved section 4C, bringing the curved outside portion of the main body 7 closer to the traveling rail 4. The transport vehicle 6 according to the above example embodiment is provided with the contact roller 61 coming into contact with the curved outside portion of the traveling rail 4 in the curved section 4C from below on the upper surface of the main body 7. This enables, when the curved outside portion of the main body 7 is about to approach the traveling rail 4, the contact roller 61 to come into contact with the curved outside portion of the traveling rail 4, and the reaction force at that time restricts the approaching of the curved outside portion of the main body 7 to the traveling rail 4. Consequently, the inclination of the main body 7, and thus the inclination of the traveling portion 50 suspending and supporting the main body 7 are prevented, and the floating amount of the traveling rollers 51 when the traveling portion 50 travels through the curved section 4C can be reduced.

In the transport vehicle 6 according to the above example embodiment, in the curved section 4C, the contact roller 61 comes into contact with one lower surface portion 41 disposed on the curved outside out of the pair of lower surface portions 41, 41. This enables the reaction force when the contact roller 61 comes into contact with the one lower surface portion 41 to restrict, the approaching of the curved outside portion of the main body 7 to the traveling rail 4 (the lower surface portion 41).

The transport vehicle 6 according to the above example embodiment includes the lifting mechanism 63 configured to lift and lower the contact roller 61 in the vertical direction. This enables, when the contact roller 61 is desired to be brought into contact with the traveling rail 4, the contact roller 61 to be surely brought into contact with the traveling rail 4, and when the contact roller 61 is desired to be separated from the traveling rail 4, the contact roller 61 to be surely separated from the traveling rail 4.

In the transport vehicle 6 according to the above example embodiment, a portion of the linear motion mechanism 64 of the lifting mechanism 63 includes the trapezoidal screw 64C, and thus a simple configuration can counter the reaction force when the contact roller 61 comes into contact with the traveling rail 4 without requiring a complicated mechanism such as a brake mechanism, for example.

In the transport vehicle 6 according to the above example embodiment, the main body controller 35 is configured or programmed to control the lifting mechanism 63 such that the contact roller 61 comes into contact with the traveling rail 4 at least when the traveling portion 50 travels through the curved section 4C. This enables the contact roller 61 to be brought into contact with the curved outside portion of the traveling rail 4 more surely in the curved section 4C.

In the transport vehicle 6 according to the above example embodiment, the contact roller 61 is rotatably provided, and the orientation of the contact roller 61 is provided so as to enable rocking. This enables the orientation of the contact roller 61 to be changed so as to be along the traveling direction of the traveling portion 50, and thus the contact roller 61 rotates well during traveling of the transport vehicle 6. This can prevent the rotating portion 61A of the contact roller 61 from sliding on the traveling rail 4 and prevent the contact roller 61 from wearing due to the traveling direction of the traveling portion 50 and the orientation of the contact roller 61 not matching.

In the transport vehicle 6 according to the above example embodiment, the contact roller 61 is provided at the central portion of the main body 7 in the traveling direction of the traveling portion 50, and thus even if the orientation of the contact roller 61 is not able to oscillate, there is a high possibility that the traveling direction of the traveling portion 50 and the orientation of the contact roller 61 will match in the curved section 4C. This can prevent the rotating portion 61A of the contact roller 61 from sliding on the traveling rail 4 and prevent the rotating portion 61A of the contact roller 61 from wearing due to the traveling direction of the traveling portion 50 and the orientation of the contact roller 61 not matching.

In the transport vehicle 6 according to the above example embodiment, the main body controller 35 is configured or programmed to control the lifting mechanism 63 so as to be in the first state S1 when the transport vehicle 6 transfers the article 10 to the loading portion 9. This can prevent the main body 7 from being inclined to the left, when viewed from the front in the traveling direction of the transport vehicle 6, when the article 10 is transferred to the loading portion 9 disposed below and at the left of the traveling rail 4. In addition, when the article 10 is transferred to the loading portion 9 disposed below and at the right of the traveling rail 4, the main body 7 can be prevented from being inclined to the right.

Example embodiments of the present invention have been described above, but the present invention is not limited to the above example embodiments. Various modifications can be made without departing from the gist of the present invention.

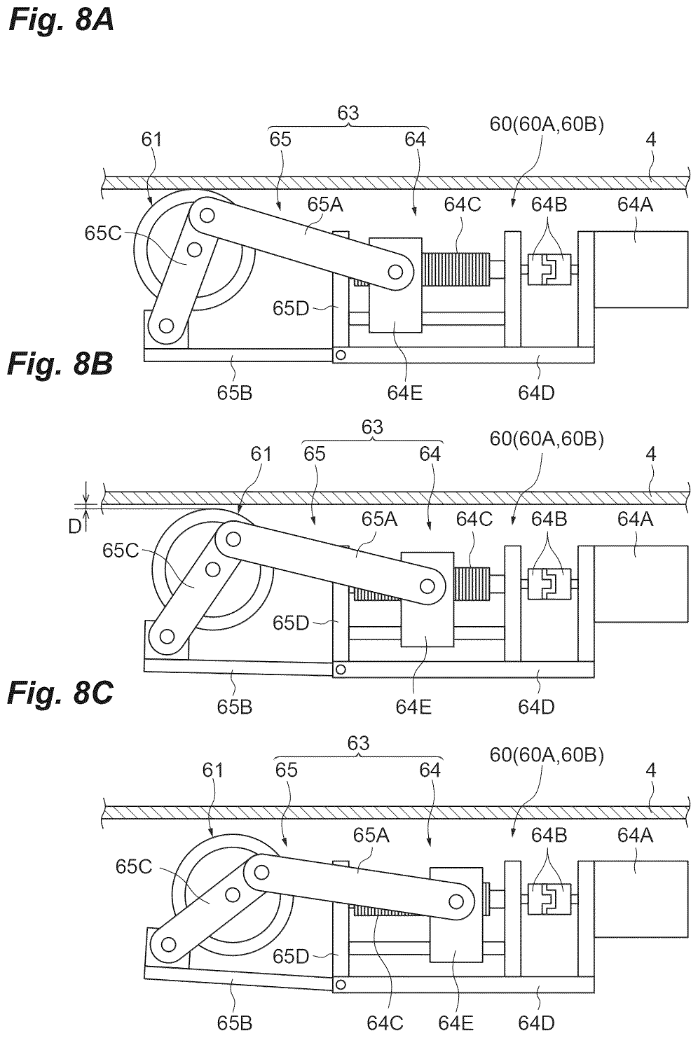

In the inclination prevention mechanism 60 according to the above example embodiments, a configuration has been described as an example in which the position of the contact roller 61 is lowered by moving the moving block 64E in the left direction, and the position of the contact roller 61 is raised by moving the moving block 64E in the right direction, but this is not limiting. For example, as illustrated in FIGS. 8A to 8C, the inclination prevention mechanism 60 may be configured to raise the position of the contact roller 61 by moving the moving block 64E in the left direction and to lower the position of the contact roller 61 by moving the moving block 64E in the right direction. Note that a description of each portion of the inclination prevention mechanism 60 is omitted.

Even with the inclination prevention mechanism 60 according to such a modification, the main body controller 35 controls the lifting mechanism 63 so as to be in a state in which the contact roller 61 comes into contact with the traveling rail 4 illustrated in FIG. 8B at least when the traveling portion 50 travels through the curved section 4C and can thereby surely bring the contact roller 61 into contact with the curved outside portion of the traveling rail 4 in the curved section 4C.

In the above example embodiments and the above modifications, examples provided with the lifting mechanism 63 to lift and lower the contact roller 61 have been described, but, for example, the lifting mechanism 63 need not be provided. In this case, for example, as illustrated in FIG. 5B, the contact roller 61 may be disposed at a position separate from the lower surface portion 41 of the traveling rail 4 by the distance D.

In the above example embodiments and modifications, as examples of the linear motion mechanism 64 included in the inclination prevention mechanism 60, the trapezoidal screw 64C and the moving block 64E to which the trapezoidal screw 64C is screwed have been described as an example, but, for example, a mechanism such as a ball screw, a linear guide, or a rack and pinion may be used.

In the above example embodiments and modifications, examples have been described in which the linear motion mechanism 64 included in the inclination prevention mechanism 60 is controlled even during transfer of the article 10 from the main body 7 to the loading portion 9 to make, for example, the state illustrated in FIG. 5A or 8A, but such control need not be executed.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-7. (canceled)

8. An overhead transport vehicle comprising:
a traveling portion including traveling wheels to roll on a traveling rail; and
a main body supported by the traveling portion via a suspension and configured to hold an object to be transported;
the overhead transport vehicle being provided with a contact roller to contact with a curved outside portion of the traveling rail in a curved section from below on an upper surface of the main body facing the traveling rail in a vertical direction.

9. The overhead transport vehicle according to claim 8, wherein
the traveling rail includes:
a slit portion through which the suspension is movable during traveling of the traveling portion; and
a pair of rolling portions on which the traveling wheels roll, the pair of rolling portions facing each other across the slit portion in a width direction perpendicular or substantially perpendicular to both the vertical direction and a traveling direction of the traveling portion; and
the contact roller is able to contact with one of the pair of rolling portions on a curved outside in the curved section.

10. The overhead transport vehicle according to claim 9, further comprising an elevator to lift and lower the contact roller in the vertical direction.

11. The overhead transport vehicle according to claim 10, wherein a portion of a linear motion mechanism included in the elevator includes a trapezoidal screw.

12. The overhead transport vehicle according to claim 10, further comprising a controller configured or programmed to control the lifting mechanism such that the contact roller comes into contact with the traveling rail at least when the traveling portion travels through the curved section.

13. The overhead transport vehicle according to claim 8, wherein the contact roller is rotatably provided, and an orientation of the contact roller enables rocking with respect to a direction perpendicular or substantially perpendicular to a rotational axis direction when viewed from the vertical direction.

14. The overhead transport vehicle according to claim 8, wherein the contact roller is provided at a central portion of the main body in a traveling direction of the traveling portion.
